(19) United States
(12) Patent Application Publication
(10) Pub. No.: US 2026/0309816 A1
(43) Pub. Date: Oct. 8, 2026

(54) MAGNET SENSOR DEVICE AND PRODUCTION METHOD FOR A MAGNET SENSOR DEVICE

(71) Applicant: Robert Bosch GmbH, Stuttgart (DE)

(72) Inventors: Christoph Schelling, Stuttgart (DE); Nico Kerber, Reutlingen (DE)

(21) Appl. No.: 19/638,181

(22) Filed: Apr. 3, 2026

(30) Foreign Application Priority Data
Apr. 8, 2025 (DE) 10 2025 113 761.7

(51) Int. Cl. G01R 33/07; G01R 33/09

(52) U.S. Cl. CPC G01R 33/07; G01R 33/09

(57) ABSTRACT

A magnet sensor device. The magnet sensor device has at least one measuring bridge device, which has at least one measuring bridge and at least four sensor elements, wherein a first sensor element is of a first sensor element type and has a first sensitivity and/or a first measuring range along a specified first sensing axis and is arranged in a first sensor element layer on and/or above the first substrate surface, wherein a second sensor element is arranged in a second sensor element layer, which lies on one side of the first sensor element layer, and wherein a second sensor element type of the second sensor element differs from the first sensor element type of the first sensor element.

### CROSS REFERENCE

The present application claims the benefit under 35 U.S.C. § 119 of Germany Patent Application No. DE 10 2025 113 761.7 filed on Apr. 8, 2025, which is expressly incorporated herein by reference in its entirety.

### FIELD

The present disclosure relates to a magnet sensor device. Likewise, the present disclosure relates to a production method for a magnet sensor device.

### BACKGROUND INFORMATION

U.S. Patent No. US 10,418,546 B2 describes a magnetic sensor that comprises a plurality of measuring bridges, first sensor elements of which are integrated in a first sensor element layer and second sensor elements of which are integrated in a second sensor element layer, wherein the second sensor element layer lies, in a spatial direction oriented perpendicularly to a substrate surface of the magnetic sensor, on one side of the first sensor element layer and spaced apart from the first sensor element layer.

### SUMMARY

The present disclosure provides a magnet sensor device and a production method for a magnet sensor device.

According to an example embodiment, the magnet sensor device, includes: a first substrate having a first substrate surface; and at least one measuring bridge device, which comprises at least one measuring bridge, has at least four sensor elements, and is configured in such a way that at least one measured value with respect to a magnetic field present at the measuring bridge device is determinable taking into consideration bridge potentials tapped at tap contact points of the measuring bridge device; wherein a first sensor element of the at least four sensor elements, which is of a first sensor element type and has a first sensitivity and/or a first measuring range along a specified first sensing axis, is arranged in a first sensor element layer on and/or above the first substrate surface, and wherein a second sensor element of the at least four sensor elements is arranged in a second sensor element layer, and the second sensor element layer lies, in a spatial direction oriented perpendicularly to the first substrate surface, on one side of the first sensor element layer spaced apart from the first sensor element layer; wherein a second sensor element type of the second sensor element differs from the first sensor element type of the first sensor element, a second sensing axis of the second sensor element differs from the first sensing axis of the first sensor element, and/or a second sensitivity and/or a second measuring range of the second sensor element differs from the first sensitivity and/or the first measuring range of the first sensor element.

The present disclosure provides advantageous options for the measurement of measured variables, in a manner that is particularly robust against stray fields and/or has relatively low angular error, such as, e.g., magnetic field components, of a magnetic field to be examined using a monolithic structure. The measured values obtained by means of the present disclosure are in particular also robust with respect to inhomogeneous stray fields, in a spatial direction oriented parallel to the first substrate surface of the particular magnet sensor device. Additionally, the present disclosure enables the coaxial measurement of at least two magnetic field components at a lateral position, i.e., at a position defined by means of two spatial directions oriented parallel to the first substrate surface. As also becomes clear based on the following description, the present disclosure facilitates the miniaturization of magnet sensor devices at comparatively low production costs.

A further advantage of the present disclosure over the related art described above is the option thus realized of measuring different physical measured variables, such as magnetic field strength components along different spatial directions/sensing axes. Correspondingly, the present disclosure also enables an extension of a dynamic measuring range of a magnet sensor device thus realized by combining sensor elements with different sensitivities and/or different measuring ranges. This can be used for the miniaturization of magnet sensor devices, by means of which magnetic field strengths along various spatial directions and/or magnetic field strengths in each case within a comparatively large measuring range can be measured with a high degree of accuracy.

In an advantageous example embodiment of the magnet sensor device, the first sensor element is interconnected with at least one third sensor element of the at least four sensor elements arranged in the first sensor element layer to form a first voltage divider of a measuring bridge or a first measuring bridge, and the second sensor element is interconnected with at least one fourth sensor element of the at least four sensor elements arranged in the second sensor element layer to form a second voltage divider of the measuring bridge or a second measuring bridge, wherein all sensor elements of the first voltage divider or the first measuring bridge are of the first sensor element type and have the first sensitivity and/or the first measuring range along the respectively specified first sensing axis, and all sensor elements of the second voltage divider or the second measuring bridge are of the second sensor element type and have the second sensitivity and/or the second measuring range along the specified second sensing axis. As becomes clear based on the following description, this can be used for realizing a plurality of different magnet sensor devices with different sensing axes and/or different sensitivities, or different measuring ranges.

For example, the first sensor element type can differ from the second sensor element type, and the first sensor element type and the second sensor element type can in each case be selected from a group comprising a TMR sensor element, a GMR sensor element, an AMR sensor element and/or a Hall sensor element. The particular type of sensor elements in the first sensor element layer can thus differ from the particular type of sensor elements in the second sensor element layer.

Alternatively or additionally, the first sensing axis can be oriented at an angle of inclination between 60° and 120° relative to the second sensing axis. Thus, within a comparatively small volume of the embodiment of the magnet sensor device described here, the magnetic field strength of a magnetic field to be examined can be determined along the two sensing axes that differ significantly from one another.

In a further advantageous example embodiment, the first sensing axis is oriented at an angle of inclination less than or equal to 10° relative to the second sensing axis, wherein the first sensitivity differs from the second sensitivity and/or the first measuring range differs from the second measuring range. The embodiment of the magnet sensor device described here enables measurements within a comparatively large dynamic measuring range by combining sensor elements with different sensitivities/measuring ranges within a comparatively small volume.

For example, the first sensor element layer can at least partially cover the first substrate surface and/or at least one layer at least partially covering the first substrate surface, wherein the second sensor element layer at least partially covers at least one intermediate layer at least partially covering the first sensor element layer. The embodiment of the magnet sensor device described here can be produced with relatively little labor and comparatively inexpensively.

Advantageously, the first sensor element layer can at least partially cover the first substrate surface and/or at least one first layer at least partially covering the first substrate surface, wherein the second sensor element layer at least partially covers a second substrate surface of a second substrate and/or at least one second layer at least partially covering the second substrate surface, and wherein at least one bond connection is formed between a first outer surface of the first sensor element layer facing away from the first substrate surface and a second outer surface of the second sensor element layer facing away from the second substrate surface. The embodiment of the magnet sensor device described here is also comparatively easy and relatively inexpensive to produce.

In an alternative example embodiment of the magnet sensor device, the first sensor element layer at least partially covers the first substrate surface and/or at least one first layer at least partially covering the first substrate surface, wherein the second sensor element layer at least partially covers a second substrate surface of a second substrate and/or at least one second layer at least partially covering the second substrate surface, and wherein at least one bond connection is formed between an outer surface of the first sensor element layer facing away from the first substrate surface and a further substrate surface of the second substrate facing away from the second substrate surface. The production of the embodiment of the magnet sensor device described here is also possible with relatively little labor and at comparatively low production costs.

Advantageously, a center tap contact point can be formed as a tap contact point in a conductor track electrically connecting the first sensor element to the second sensor element. This facilitates the electrical contacting of the at least one measuring bridge of the measuring bridge device despite its comparatively high density of sensor elements per area of the first substrate surface.

In particular, at least the four sensor elements can be electrically connected to a common supply voltage. This facilitates power supply for the at least four sensor elements of the at least one measuring bridge.

Furthermore, carrying out a corresponding production method for a magnet sensor device also provides the advantages described above. It is expressly pointed out that the production method can be further developed according to the example embodiments of the magnet sensor device explained above.

### BRIEF DESCRIPTION OF THE DRAWINGS

Further features and advantages of the present disclosure will be explained in the following with reference to the figures.

FIGS. 1-9 are, in each case, a schematic representation of various example embodiments of the magnet sensor device.

FIG. 10 shows a flow chart for explaining an example embodiment of a production method for a magnet sensor device.

### DETAILED DESCRIPTION OF EXAMPLE EMBODIMENTS

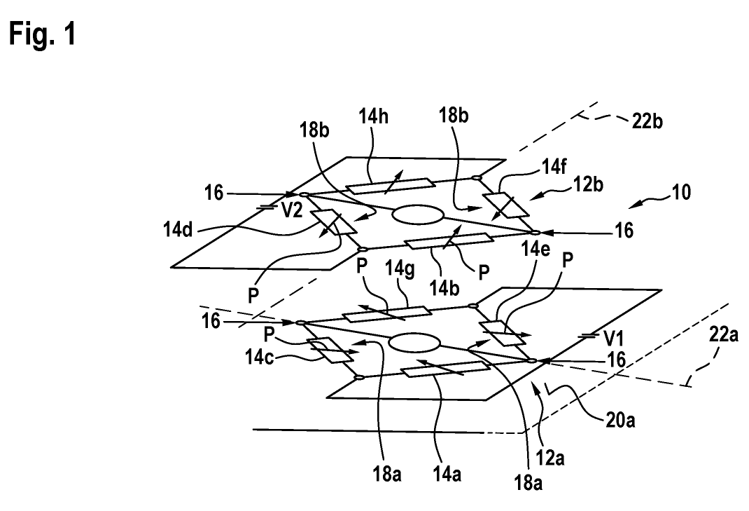

FIG. 1 is a schematic representation of a first embodiment of the magnet sensor device.

The magnet sensor device schematically reproduced in FIG. 1 has at least one measuring bridge device 10. The measuring bridge device 10 is to be understood as electronics having at least one measuring bridge 12a and 12b and at least four sensor elements 14a to 14h. The at least one measuring bridge 12a and 12b of the measuring bridge device 10 can be formed by a series and/or parallel circuit of the respective sensor elements 14a to 14h thereof. Moreover, the measuring bridge device 10 is configured in such a way that at least one measured value with respect to a magnetic field present at the measuring bridge device 10 is determinable/is determined taking into consideration bridge potentials tapped at tap contact points 16 of the measuring bridge device 10. The at least one measured value can be, e.g., a magnetic field strength of the magnetic field to be examined.

As can be seen in FIG. 1, a first sensor element 14a of the at least four sensor elements 14a to 14h is arranged in a first sensor element layer 18a. In contrast, a second sensor element 14b of the at least four sensor elements 14a to 14h is integrated in a second sensor element layer 18b. Whereas the first sensor element layer 18a is formed on and/or above a first substrate surface 20a of a first substrate (not illustrated), the second sensor element layer 18b lies, in a spatial direction oriented perpendicularly to the first substrate surface 20a, on one side of the first sensor element layer 18a spaced apart from the first sensor element layer 18a. A spacing of the first sensor element layer 18a from the second sensor element layer 18b can be, e.g., less than or equal to 100 μm (micrometers), for example less than or equal to 50 μm (micrometers), in particular less than or equal to 10 μm (micrometers). The design of the magnet sensor device described here, with an arrangement/distribution of at least the four sensor elements 14a to 14d over at least the two sensor element layers 18a and 18b, facilitates the miniaturization of the magnet sensor device. Additionally, by means of the arrangement/distribution of at least the four sensor elements 14a to 14d over at least the two sensor element layers 18a and 18b, the robustness of the measured values obtained by means of the magnet sensor device with respect to inhomogeneous stray fields (in a spatial direction oriented parallel to the first substrate surface 20a) is increased. The comparatively small spacing between the first sensor element layer 18a and the second sensor element layer 18b additionally ensures that the measurements carried out by means of the magnet sensor device are robust with respect to field gradients in a spatial direction oriented perpendicularly to the first substrate surface 20a.

The first sensor element 14a is of a first sensor element type and has a first sensitivity and/or a first measuring range along a specified first sensing axis 22a. The first sensor element type can, for example, be selected from a group comprising a TMR sensor element (tunnel magnetoresistance), a GMR sensor element (giant magnetoresistance), an AMR sensor element (anisotropic magnetoresistive effect) and/or a Hall sensor element. The second sensor element 14b is of a second sensor element type and has a second sensitivity and/or a second measuring range along a specified second sensing axis 22b. The second sensor element type can also in each case be selected from the group comprising a TMR sensor element, a GMR sensor element, an AMR sensor element and/or a Hall sensor element. However, the second sensor element type of the second sensor element 14b differs from the first sensor element type of the first sensor element 14a, the second sensing axis 22b of the second sensor element 14b differs from the first sensing axis 22a of the first sensor element 14a and/or the second sensitivity and/or the second measuring range of the second sensor element 14b along the second sensing axis 22b differs from the first sensitivity and/or the first measuring range of the first sensor element 14a along the first sensing axis 22a. As becomes clear based on the following description, the magnet sensor device explained here can therefore be used in a versatile manner.

As schematically reproduced in FIG. 1, for example, the first sensing axis 22a can be oriented at an angle of inclination between 60° and 120°, e.g., at an angle of inclination between 70° and 110°, in particular at an angle of inclination between 80° and 100°, especially at an angle of inclination between 85° and 95°, relative to the second sensing axis 22b. Preferably, the first sensing axis 22a is oriented perpendicularly to the second sensing axis 22b. Thus, within a volume the covers a comparatively small area on the first substrate surface 20a, the magnetic field strength of the magnetic field to be examined can be determined in a positionally identical manner along the two sensing axes 22a and 22b that differ significantly from one another. For this reason, when examining the magnetic field within the comparatively small volume occupied by the at least four sensor elements 14a to 14h, it is no longer necessary to limit the examination to only one of the sensing axes 22a or 22b. Moreover, the embodiment described here facilitates the miniaturization of a magnet sensor device that can be used at least as a 2D magnetic sensor, in particular as a 3D magnetic sensor.

Optionally, the first sensor element type can be the same as the second sensor element type or can differ from the second sensor element type. Likewise, the first sensitivity of the first sensor element 14a along the first sensing axis 22a can be the same as or different from the second sensitivity of at least the second sensor element 14b along the second sensing axis 22b. Correspondingly, the first measuring range can differ from the second measuring range. Thus, there is substantial design freedom in forming the magnet sensor device schematically reproduced in FIG. 1.

The first sensor element 14a can be interconnected with at least one third sensor element 14c of the at least four sensor elements 14a to 14h arranged in the first sensor element layer 18a to form a first measuring bridge 12a. Correspondingly, the second sensor element 14b can also be interconnected with at least one fourth sensor element 14d of the at least four sensor elements 14ato 14h arranged in the second sensor element layer 18b to form a second measuring bridge 12b. Preferably, in this case, all sensor elements 14a, 14c, 14e and 14g of the first measuring bridge 12a are of the first sensor element type and have the first sensitivity and/or the first measuring range along the specified first sensing axis 22a, while all sensor elements 14b, 14d, 14f and 14h of the second measuring bridge 12b are of the second sensor element type and have the second sensitivity and/or the second measuring range along the specified second sensing axis 22b. Merely by way of example, in the embodiment of FIG. 1, all sensor elements 14a, 14c, 14e and 14g of the first measuring bridge 12a are electrically connected to a first supply voltage V1, and all sensor elements 14b, 14d, 14f and 14h of the second measuring bridge 12b are electrically connected to a second supply voltage V2.

The sensing axes 22a and 22b differing from one another can be specified, for example, by means of a polarization/orientation of at least one material from which the respective sensor elements 14a to 14h are formed. “Specification of the first/second sensing axis 22a or 22b” can be understood as both a polarization/orientation of the particular material in a certain direction and a polarization/orientation of the particular material in a complementary opposite direction. In particular, a permanently impressed magnetic polarization/orientation of the particular material can be used, wherein the specific polarization/orientation of the particular material of an individual sensor element 14a to 14h of the respective sensor elements 14a to 14h, which define the first sensing axis 22a or the second sensing axis 22b, can be oriented parallel or anti-parallel relative to one another. Preferably, however, all individual polarizations/orientations lie parallel to a definable plane, such as, e.g., the first substrate surface 20a. In particular, the polarization/orientation of the material can relate to the magnetic reference layer of a GMR or TMR sensor element.

Optionally, the first sensor element 14a can also have the same coordinates as the second sensor element 14b with respect to two spatial directions oriented parallel to the first substrate surface 20a and perpendicularly to one another. Especially, all sensor elements 14a, 14c, 14e and 14g in the first sensor element layer 18a can have, with respect to the two spatial directions oriented parallel to the first substrate surface 20a and perpendicularly to one another, coordinates at which in each case one sensor element 14b, 14d, 14f and 14h is present in the second sensor element layer 18b. This ensures particularly high robustness with respect to stray fields of the magnet sensor device realized in this way, since, if applicable, an identical field is present at one particular sensor element 14a to 14h both in the first sensor element layer 18a and in the second sensor element layer 18b.

For example, the sensor elements 14a to 14h integrated in at least the two sensor element layers 18a and 18b can each have a reference layer. As graphically reproduced by means of arrows P in FIG. 1, in this case the particular magnetic polarization/orientation of the reference layers of the sensor elements 14a to 14hcan be oriented in such a way that the sensor elements 14a to 14h arranged in different sensor element layers 18a and 18b and having identical coordinates with respect to two spatial directions oriented parallel to the first substrate surface 20a and perpendicularly to one another have a complementary magnetic polarization/orientation of their reference layers. A complementary magnetic polarization/orientation of the reference layers can be understood as an angle enclosed between the reference layers of 90° or 180°. A particular free layer of the particular sensor element 14a to 14d can have a preferred orientation “rotated” by ±90° relative to the polarization/orientation of the reference layer of the same sensor element 14a to 14d.

In a further embodiment, the sensor elements 14a to 14d can in each case have a plurality of XMR resistance elements connected in series.

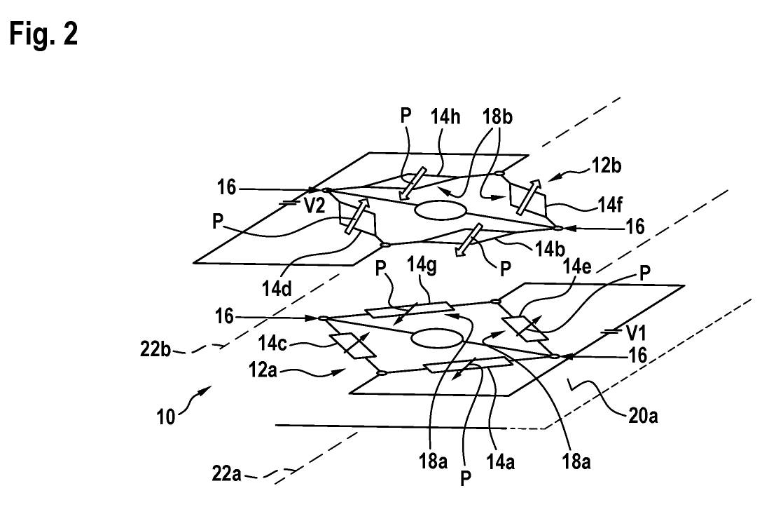

FIG. 2 is a schematic representation of a second embodiment of the magnet sensor device.

In contrast to the above-described embodiment of FIG. 1, in the magnet sensor device of FIG. 2 the first sensing axis 22a and the second sensing axis 22b are oriented relative to one another in such a way that an angle of inclination less than or equal to 10° is present between the first sensing axis 22a and the second sensing axis 22b. In particular, the first sensing axis 22a can be oriented at an angle of inclination less than or equal to 5°, especially at an angle of inclination less than or equal to 3°, relative to the second sensing axis 22b. Preferably, the sensing axes 22a and 22b are parallel to one another. However, in the embodiment of FIG. 2 the first sensitivity of at least the first sensor element 14a along the first sensing axis 22a differs from the second sensitivity of at least the second sensor element 14b along the second sensing axis 22b. Correspondingly, the first measuring range can also differ from the second measuring range. As graphically reproduced by means of the different thicknesses of the arrows P in FIG. 2, all sensor elements 14a, 14c, 14e and 14g of the first measuring bridge 12a can have the first sensitivity and/or the first measuring range along the first sensing axis 22a, and all sensor elements 14b, 14d, 14f and 14h of the second measuring bridge 12b can have the second sensitivity and/or the second measuring range along the second sensing axis 22b, wherein the first sensitivity differs from the second sensitivity and/or the first measuring range differs from the second measuring range. Therefore, the magnet sensor device of FIG. 2 can have an advantageously large measuring range within which the magnetic field strength of the magnetic field to be examined can be ascertained with high measuring accuracy.

Especially, all sensor elements 14a, 14c, 14e and 14g in the first sensor element layer 18a can have the first sensitivity and/or the first measuring range along the first sensing axis 22a, and all sensor elements 14b, 14d, 14f and 14h in the second sensor element layer 18b can have the second sensitivity and/or the second measuring range, wherein the first sensitivity differs from the second sensitivity and/or the first measuring range differs from the second measuring range. The different sensitivities/measuring ranges of the sensor elements 14a to 14h in the two sensor element layers 18a and 18b can be realized by different design configurations. The distribution of the respective sensor elements 14a to 14h over the two different sensor element layers 18a and 18b simplifies the formation of the sensor elements 14a to 14h with different designs, such as, e.g., different layer structures.

In particular, at least the first sensor element 14a/all sensor elements 14a, 14c, 14e and 14g in the first sensor element layer 18a can have, compared with the second sensor element 14b/all sensor elements 14b, 14d, 14f and 14h in the second sensor element layer 18b, a different design and/or a different layer material structure. Alternatively or additionally, at least the first sensor element 14a/all sensor elements 14a, 14c, 14e and 14g in the first sensor element layer 18a can have, compared with at least the second sensor element 14b/all sensor elements 14b, 14d, 14f and 14h in the second sensor element layer 18b, different presetting, different bias and/or different field shielding. Due to the particular presetting, the particular bias or the particular field shielding, the resulting measuring range of all sensor elements 14a, 14c, 14e and 14g in the first sensor element layer 18a and/or of all sensor elements 14b, 14d, 14f and 14h in the second sensor element layer 18b can be shifted and/or expanded in a targeted manner. In particular, by means of so-called biasing, an extended measuring range can be easily obtained for all sensing elements 14a, 14c, 14e and 14g in the first sensing element layer 18a and/or for all sensing elements 14b, 14d, 14f and 14h in the second sensing element layer 18b. By combining different sensitivities/measuring ranges of the sensor elements 14a to 14h, larger/expanded measuring ranges can be realized by means of corresponding calculation of the bridge potentials tapped at the measuring bridge device 10.

For example, at least the first sensor element 14a/all sensor elements 14a, 14c, 14e and 14g in the first sensor element layer 18a can in each case be a “conventional” TMR sensor element, a “conventional” GMR sensor element or a “conventional” AMR sensor element, while at least the second sensor element 14b/all sensor elements 14b, 14d, 14f and 14h in the second sensor element layer 18b is/are a vortex TMR sensor element, a vortex GMR sensor element or a vortex AMR sensor element. Correspondingly, at least the first sensor element 14a/all sensor elements 14a, 14c, 14e and 14g in the first sensor element layer 18a can in each case be a “bottom spin valve” TMR sensor element, a “bottom spin valve” GMR sensor element and/or a “bottom spin valve” AMR sensor element, while at least the second sensor element 14b/all sensor elements 14b, 14d, 14f and 14h in the second sensor element layer 18b is/are a “dual spin valve” TMR sensor element, a “dual spin valve” GMR sensor element and/or a “dual spin valve” TMR sensor element. Optionally, at least the first sensor element 14a/all sensor elements 14a, 14c, 14e and 14g in the first sensor element layer 18a can also be polarized in saturation, while at least the second sensor element 14b/all sensor elements 14b, 14d, 14f and 14h in the second sensor element layer 18b is/are not saturated. Alternatively, the sensor elements 14a, 14c, 14e and 14g formed as TMR sensor elements, as GMR sensor elements or as AMR sensor elements in the first sensor element layer 18a can also have a different shape/geometry compared with all sensor elements 14b, 14d, 14f and 14h in the second sensor element layer 18b, which can lead to different field measuring ranges.

With respect to further features and properties of the magnet sensor device of FIG. 2 and advantages thereof, reference is made to the description of the above-described embodiment of FIG. 1.

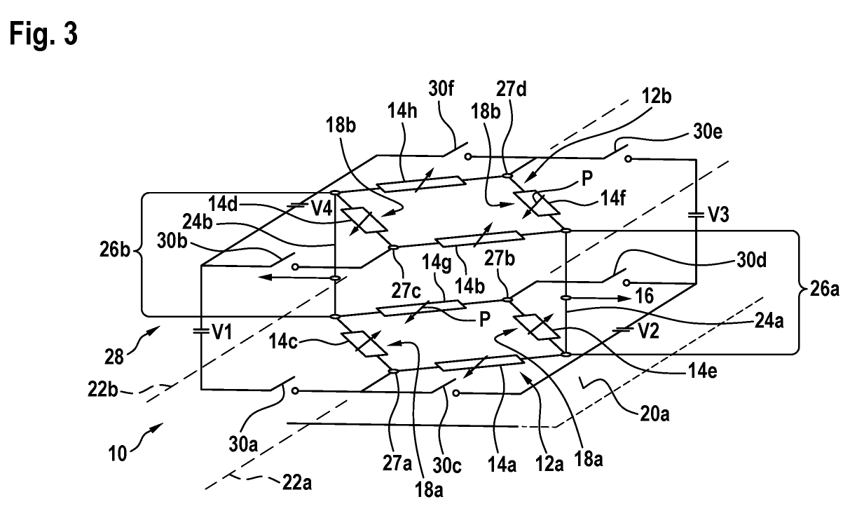

FIG. 3 is a schematic representation of a third embodiment of the magnet sensor device.

In the example of FIG. 3, the first sensor element type of at least the first sensor element 14a differs from the second sensor element type of at least the second sensor element 14b. This is possible even if the first sensor element type and the second sensor element type are in each case selected from the group comprising a TMR sensor element, a GMR sensor element, an AMR sensor element and/or a Hall sensor element. In particular, all sensor elements 14a, 14c, 14e and 14g of the first measuring bridge 12a can be of the first sensor element type, and all sensor elements 14b, 14d, 14f and 14h of the second measuring bridge 12b can be of the second sensor element type, wherein the first sensor element type differs from the second sensor element type. The first sensor element type can also differ from the second sensor element type if all sensor elements 14a, 14c, 14e and 14g in the first sensor element layer 18a are of the first sensor element type and all sensor elements 14b, 14d, 14f and 14h in the second sensor element layer 18b are of the second sensor element type.

Merely by way of example, in the magnet sensor device of FIG. 3 the sensing axes 22a and 22b are oriented parallel to one another. Optionally, the first sensitivity and/or the first measuring range of at least the first sensor element 14a/all sensor elements 14a, 14c, 14e and 14g in the first sensor element layer 18a along the first sensing axis 22a can be the same as or different from the second sensitivity and/or the second measuring range of at least the second sensor element 14b/all sensor elements 14b, 14d, 14f and 14h in the second sensor element layer 18b along the second sensing axis 22b.

As is also graphically reproduced in FIG. 3, at least one of the tap contact points 16 is formed in a conductor track 24a electrically connecting the first sensor element 14a to the second sensor element 14b. The conductor track 24a is to be understood as a conduction path that extends from the first sensor element 14a to the second sensor element 14b and does not pass through any further sensor element 14c to 14h of the measuring bridge device 10. Preferably, the conductor track 24a comprises a conductor track portion 26a that extends through the volume lying between the first sensor element layer 18a and the second sensor element layer 18b. The conductor track portion 26a can in particular be oriented perpendicularly to the first substrate surface 20a. Advantageously, the at least one tap contact point 16 in the conductor track 24a electrically connecting the first sensor element 14a to the second sensor element 14b is a center tap contact point 16. This facilitates the tapping of bridge potentials at the measuring bridge device 10 even in the case of miniaturization thereof. Preferably, the center tap contact point 16 of the conductor track 24a lies within the conductor track portion 26a thereof oriented perpendicularly to the first substrate surface 20a.

Moreover, at least one of the tap contact points 16 can additionally be formed in a further conductor track 24b electrically connecting the third sensor element 14c to the fourth sensor element 14d. The conductor track 24b can be interpreted as a conduction path that extends from the third sensor element 14c to the fourth sensor element 14d and does not pass through any further sensor element 14a, 14b and 14e to 14h of the measuring bridge device 10. The conductor track 24b can also comprise a conductor track portion 26b that extends through the volume lying between the first sensor element layer 18a and the second sensor element layer 18b. The conductor track portion 26b is preferably oriented perpendicularly to the first substrate surface 20a. Correspondingly, it is also advantageous if the at least one tap contact point 16 in the further conductor track 24b electrically connecting the third sensor element 14c to the fourth sensor element 14d is in each case a center tap contact point 16. In particular, the center tap contact point 16 of the conductor track 24b can be arranged within the conductor track portion 26b thereof oriented perpendicularly to the first substrate surface 20a. If applicable, the sensor elements 14a to 14d can be connected to one another via their center tap contact points 16 in a regular manner or in a crosswise manner. Thus, potential tapping is required only in one of the sensor element layers 18a or 18b.

In contrast to the above-described embodiments, in the magnet sensor device of FIG. 3 the first Wheatstone bridge 12a formed in the first sensor element layer 18a, which has the first sensor element 14a, the third sensor element 14c, a fifth sensor element 14e and a seventh sensor element 14g, and the second Wheatstone bridge 12b formed in the second sensor element layer 18b, which comprises the second sensor element 14b, the fourth sensor element 14d, a sixth sensor element 14f and an eighth sensor element 14h, are interconnected with one another. A first bridge supply point 27a of the first Wheatstone bridge 12a lies between the first sensor element 14a and the third sensor element 14c, while a second bridge supply point 27b of the first Wheatstone bridge 12a is arranged between the fifth sensor element 14e and the seventh sensor element 14g. Correspondingly, a third bridge supply point 27c of the second Wheatstone bridge 12b lies between the second sensor element 14b and the fourth sensor element 14d, while a fourth bridge supply point 27d of the second Wheatstone bridge 12b is arranged between the sixth sensor element 14f and the eighth sensor element 14h.

Advantageously, the first Wheatstone bridge 12a and the second Wheatstone bridge 12b are interconnected in such a way that a 6-measuring-bridge circuit 28 comprising the Wheatstone bridges 12a and 12b is realized, i.e., a first measuring bridge with the sensing elements 14a-14e-14g-14c, a second measuring bridge with the sensing elements 14a-14b-14c-14d, a third measuring bridge with the sensing elements 14a-14f-14h-14c, a fourth measuring bridge with the sensing elements 14e-14g-14h-14f,

a fifth measuring bridge with the sensing elements 14e-14b-14g-14d and a sixth measuring bridge with the sensing elements 14b-14f-14h-14d can be configured. For this purpose, the first bridge supply point 27a is electrically connected via a first switch 30a to one pole of a first supply voltage V1, while the third bridge supply point 27c is electrically connected via a second switch 30b to another pole of the first supply voltage V1. The first bridge supply point 27a is additionally electrically connected via a third switch 30c to one pole of a second supply voltage V2, the other pole of which is electrically connected via a fourth switch 30d to the second bridge supply point 27b. The second bridge supply point 27b is additionally electrically connected via the fourth switch 30d to one pole of a third supply voltage V3, while the fourth bridge supply point 27d is electrically connected via a fifth switch 30e to another pole of the third supply voltage V3. Furthermore, the fourth bridge supply point 27d is electrically connected via a sixth switch 30f to one pole of a fourth supply voltage V4, the other pole of which is electrically connected via the second switch 30b to the third bridge supply point 27c. The measuring bridge device 10 of FIG. 3 thus realizes six “configurable measuring bridges,” which can be realized by opening and closing the switches 30a to 30f. Depending on which of the switches 30a to 30f is closed, different bridge potentials can be tapped and evaluated. This allows averaging and thus also higher robustness with respect to stray fields.

With respect to further features and properties of the magnet sensor device of FIG. 3 and advantages thereof, reference is made to the description of the embodiments of FIG. 1 and 2.

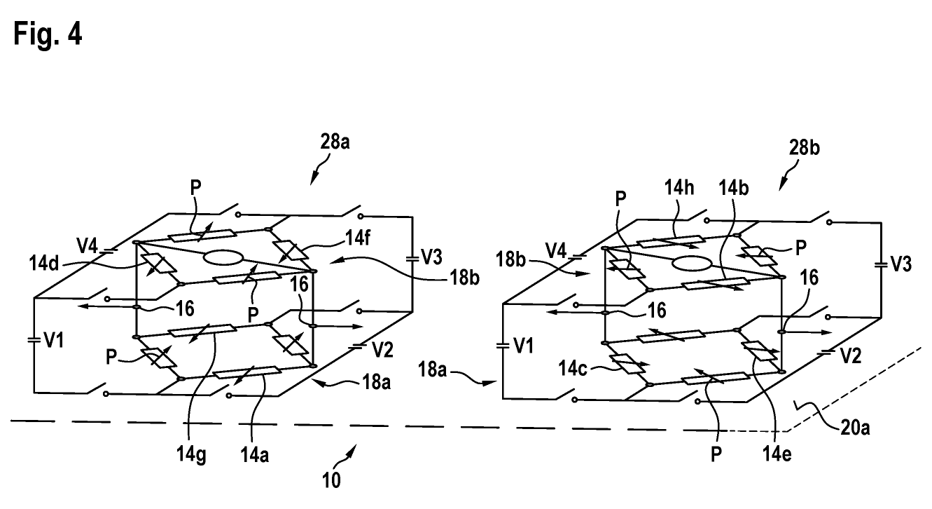

FIG. 4 is a schematic representation of a fourth embodiment of the magnet sensor device.

As a further development relative to the embodiment of FIG. 3, the magnet sensor device of FIG. 4 has two 6-measuring-bridge circuits 28a and 28b, wherein the sensing axes 22a and 22b of a first 6-measuring-bridge circuit 28a of the 6-measuring-bridge circuits 28a and 28b are oriented perpendicularly to the sensing axes 22a and 22b of a second 6-measuring-bridge circuit 28b of the 6-measuring-bridge circuits 28a and 28b.

With respect to further features and properties of the magnet sensor device of FIG. 4 and advantages thereof, reference is made to the description of the embodiments of FIG. 1 to 3.

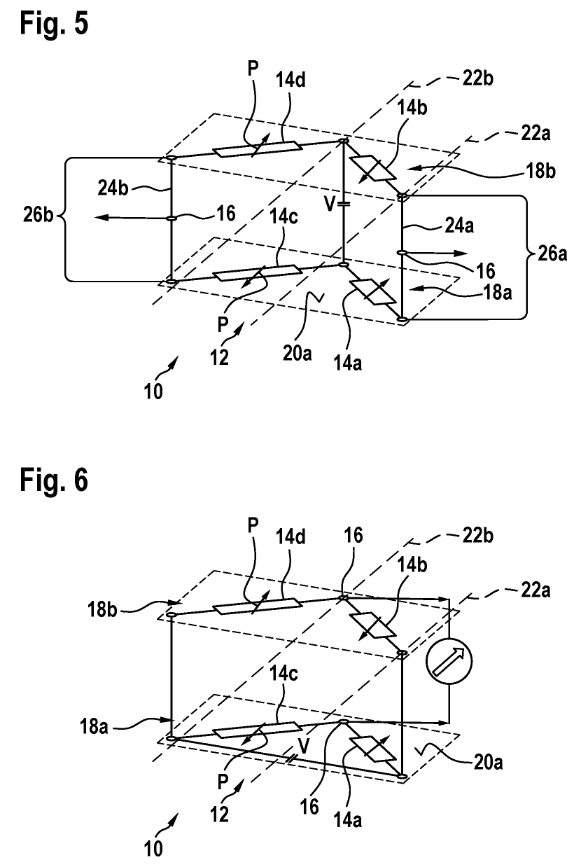

FIG. 5 is a schematic representation of a fifth embodiment of the magnet sensor device.

In contrast to the examples explained above, in the magnet sensor device of FIG. 5 the first sensor element 14a and the second sensor element 14b are interconnected to form a first voltage divider of a measuring bridge 12, and the third sensor element 14c and the fourth sensor element 14d are interconnected to form a second voltage divider of the (same) measuring bridge 12. Moreover, at least the four sensor elements 14a to 14d are electrically connected to a common supply voltage V.

The first sensor element type of at least the first sensor element 14a and optionally also of the third sensor element 14c differs from the second sensor element type of at least the second sensor element 14b and optionally also of the fourth sensor element 14d. Merely by way of example, in the magnet sensor device of FIG. 5 the sensing axes 22a and 22b are oriented parallel to one another. Optionally, the first sensitivity and/or the first measuring range of at least the first sensor element 14a and optionally also of the third sensor element 14c along the first sensing axis 22a can be the same as or different from the second sensitivity and/or the second measuring range of at least the second sensor element 14b and optionally also of the fourth sensor element 14d along the second sensing axis 22b.

With respect to further features and properties of the magnet sensor device of FIG. 5 and advantages thereof, reference is made to the description of the embodiments of FIGS. 1-4.

FIG. 6 is a schematic representation of a sixth embodiment of the magnet sensor device.

In the embodiment of FIG. 6, the first sensor element 14a and the third sensor element 14c are electrically integrated in a first voltage divider of a Wheatstone bridge 12, while the second sensor element 14b and the fourth sensor element 14d are electrically integrated in a second voltage divider of the (same) Wheatstone bridge 12. The tapping of bridge potentials is carried out in each case at the tap contact points 16 distributed over two planes and is easy to perform. The magnet sensor device of FIG. 6 is also a sensor robust with respect to stray fields, in particular with respect to inhomogeneous magnetic fields. Due to the positionally identical determination of magnetic field components in an extension plane of the sensor elements 14a to 14d that can thus be carried out, redundant measurements are possible.

With respect to further features and properties of the magnet sensor device of FIG. 6 and advantages thereof, reference is made to the description of the embodiments of FIGS. 1-5.

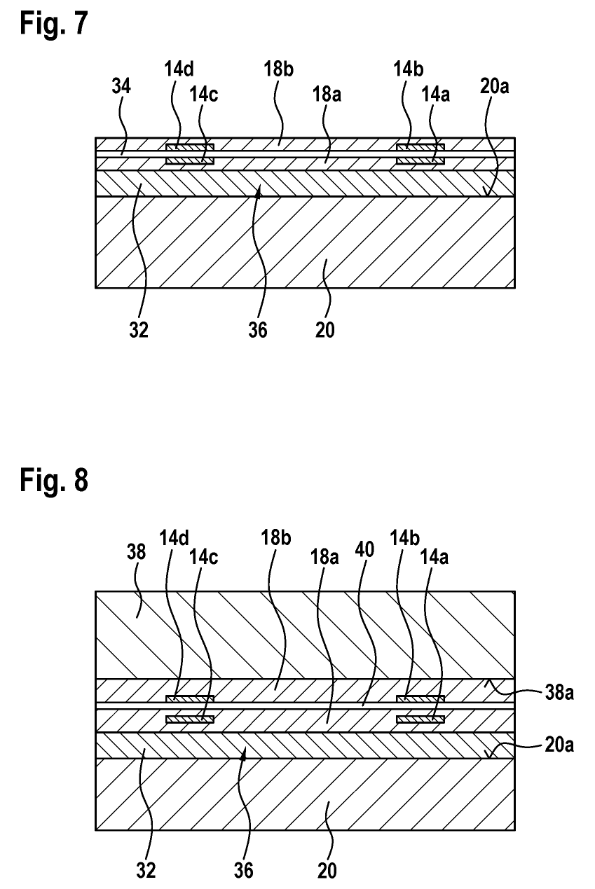

FIG. 7 is a schematic representation of a seventh embodiment of the magnet sensor device.

In the magnet sensor device of FIG. 7, the first sensor element layer 18a at least partially covers the first substrate surface 20a of the first substrate 20 and/or at least one layer 32 at least partially covering the first substrate surface 20a. The second sensor element layer 18b is formed on at least one intermediate layer 34 at least partially covering the first sensor element layer 18a so that the at least one intermediate layer 34 is at least partially covered. As can also be seen in FIG. 7, the first substrate 20 can be provided with an evaluation circuit/evaluation device 36 for further processing/evaluation of the bridge potentials tapped at the measuring bridge device 10 for determination/specification of the at least one measured value. The evaluation circuit 36 can be formed, e.g., in the at least one layer 32 lying on the first substrate surface 20a.

With respect to further features and properties of the magnet sensor device of FIG. 7 and advantages thereof, reference is made to the description of the embodiments of FIGS. 1-6.

FIG. 8 is a schematic representation of an eighth embodiment of the magnet sensor device.

Also in the magnet sensor device of FIG. 8, the first sensor element layer 18a at least partially covers the first substrate surface 20a and/or the at least one layer 32 at least partially covering the first substrate surface 20a. However, the second sensor element layer 18b is formed on a second substrate surface 38a of a second substrate 38 and/or on at least one layer, not illustrated, at least partially covering the second substrate surface 38a. Additionally, at least one bond connection 40 is formed between a first outer surface of the first sensor element layer 18a facing away from the first substrate surface 20a and a second outer surface of the second sensor element layer 18b facing away from the second substrate surface 38a. The at least one bond connection 40 is particularly advantageous, since comparatively small offsets, in particular offsets less than or equal to 1 μm (micrometer), and relatively small tilts, especially tilts less than or equal to 1°, between the sensor element layers 18a and 18b can be realized by means of carrying out bonding processes. As a rule, bonding processes provide smaller offsets and smaller tilts than alternative adhesive processes or deposition methods. By arranging the two sensor element layers 18a and 18b in such a way that their outer surfaces facing away from the first/second substrate surface 20a or 38a are oriented relative to one another, the sensor elements 14a to 14d can additionally advantageously be arranged close to one another/can advantageously be brought close to one another.

With respect to further features and properties of the magnet sensor device of FIG. 8 and advantages thereof, reference is made to the description of the embodiments of FIGS. 1-7.

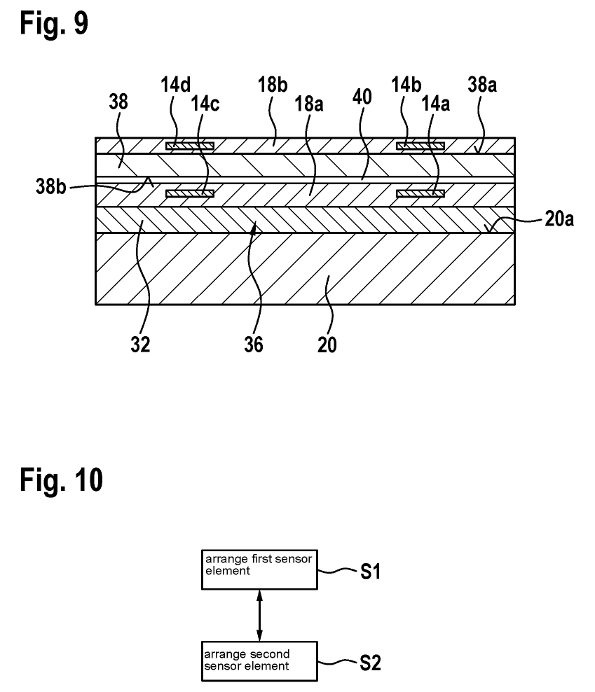

FIG. 9 is a schematic representation of a ninth embodiment of the magnet sensor device.

In contrast to the embodiment explained above, in the magnet sensor device of FIG. 9 the at least one bond connection 40 is formed between the outer surface of the first sensor element layer 18a facing away from the first substrate surface 20a and a further substrate surface 38b of the second substrate 38 facing away from the second substrate surface 38a. With respect to further features and properties of the magnet sensor device of FIG. 9 and advantages thereof, reference is made to the description of the embodiments of FIGS. 1-8.

As an optional further development of the embodiments of FIG. 8 and 9, each of the substrates 20 and 38 can also be populated with a particular evaluation circuit/evaluation device 36. This realizes an advantageously high redundancy for the magnet sensor device realized in this way with respect to a possible failure of an evaluation circuit/evaluation device 36.

All magnet sensor devices described above can be used for a plurality of applications. Possible applications are, for example, automotive or consumer applications. Each of the magnet sensor devices can be used, e.g., as an e-compass, as an angle sensor, as a position sensor, as a rotational speed sensor, as a distance sensor, as a step count sensor and/or as a current sensor, especially as a current sensor for monitoring a vehicle drive. Depending on the application, magnetic fields can in particular be measured by means of the particular magnet sensor device with regard to their magnetic field strength and their orientation.

FIG. 10 shows a flow chart for explaining an embodiment of the production method for a magnet sensor device.

In the production method described here, a measuring bridge device of the later magnet sensor device is formed. For this purpose, the measuring bridge device is configured with at least one measuring bridge and with at least four sensor elements in such a way that, during the operation of the later magnet sensor

device, at least one measured value with respect to a magnetic field present at the measuring bridge device is determinable/is determined taking into consideration bridge potentials tapped at tap contact points of the measuring bridge device. In a method step S1, a first sensor element of the at least four sensor elements, which is of a first sensor element type and has a first sensitivity and/or a first measuring range along a specified first sensing axis, is arranged in a first sensor element layer on and/or above a first substrate surface of a first substrate. Additionally, in a method step S2, a second sensor element of the at least four sensor elements is arranged in a second sensor element layer, which lies, in a spatial direction oriented perpendicularly to the first substrate surface, on one side of the first sensor element layer spaced apart from the first sensor element layer. The second sensor element is formed in such a way that a second sensor element type of the second sensor element differs from the first sensor element type of the first sensor element, a second sensing axis of the second sensor element differs from the first sensing axis of the first sensor element and/or a second sensitivity and/or a second measuring range of the second sensor element differs from the first sensitivity and/or the first measuring range of the first sensor element. The method steps S1 and S2 can be carried out in any order and optionally also at least partially overlapping.

What is claimed is:

1. A magnet sensor device, comprising:
a first substrate having a first substrate surface; and
at least one measuring bridge device, which includes at least one measuring bridge, at least four sensor elements, and is configured in such a way that at least one measured value with respect to a magnetic field present at the measuring bridge device is determinable taking into consideration bridge potentials tapped at tap contact points of the measuring bridge device;
wherein a first sensor element of the at least four sensor elements, which is of a first sensor element type and has a first sensitivity and/or a first measuring range along a specified first sensing axis, is arranged in a first sensor element layer on and/or above the first substrate surface;
wherein a second sensor element of the at least four sensor elements is arranged in a second sensor element layer, and the second sensor element layer lies, in a spatial direction oriented perpendicularly to the first substrate surface, on one side of the first sensor element layer spaced apart from the first sensor element layer; and
wherein at least one of: (i) a second sensor element type of the second sensor element differs from the first sensor element type of the first sensor element, (ii) a second sensing axis of the second sensor element differs from the first sensing axis of the first sensor element, or (iii) a second sensitivity and/or a second measuring range of the second sensor element differs from the first sensitivity and/or the first measuring range of the first sensor element.

2. The magnet sensor device according to claim 1, wherein the first sensor element is interconnected with at least one third sensor element of the at least four sensor elements arranged in the first sensor element layer to form a first voltage divider of a measuring bridge or a first measuring bridge, and the second sensor element is interconnected with at least one fourth sensor element of the at least four sensor elements arranged in the second sensor element layer to form a second voltage divider of the measuring bridge or a second measuring bridge, and wherein all sensor elements of the first voltage divider or the first measuring bridge are of the first sensor element type and have the first sensitivity and/or the first measuring range along the specified first sensing axis, and all sensor elements of the second voltage divider or the second measuring bridge are of the second sensor element type and have the second sensitivity and/or the second measuring range along the specified second sensing axis.

3. The magnet sensor device according to claim 1, wherein the first sensor element type differs from the second sensor element type, and the first sensor element type and the second sensor element type are in each case selected from a group including: a TMR sensor element, a GMR sensor element, an AMR sensor element, a Hall sensor element.

4. The magnet sensor device according to claim 1, wherein the first sensing axis is oriented at an angle of inclination between 60° and 120° relative to the second sensing axis.

5. The magnet sensor device according to claim 1, wherein the first sensing axis is oriented at an angle of inclination less than or equal to 10° relative to the second sensing axis, and wherein at least one of: the first sensitivity differs from the second sensitivity, or the first measuring range differs from the second measuring range.

6. The magnet sensor device according to claim 1, wherein the first sensor element layer at least partially covers: the first substrate surface, and/or at least one layer at least partially covers the first substrate surface, and wherein the second sensor element layer at least partially covers at least one intermediate layer at least partially covering the first sensor element layer.

7. The magnet sensor device according to claim 1, wherein the first sensor element layer at least partially covers: the first substrate surface and/or at least one first layer at least partially covering the first substrate surface, wherein the second sensor element layer at least partially covers a second substrate surface of a second substrate and/or at least one second layer at least partially covering the second substrate surface, and wherein at least one bond connection is formed between a first outer surface of the first sensor element layer facing away from the first substrate surface and a second outer surface of the second sensor element layer facing away from the second substrate surface.

8. The magnet sensor device according to claim 1, wherein the first sensor element layer at least partially covers: the first substrate surface and/or at least one first layer at least partially covering the first substrate surface, wherein the second sensor element layer at least partially covers a second substrate surface of a second substrate and/or at least one second layer at least partially covering the second substrate surface, and wherein at least one bond connection is formed between an outer surface of the first sensor element layer facing away from the first substrate surface and a further substrate surface of the second substrate facing away from the second substrate surface.

9. The magnet sensor device according to claim 1, wherein a center tap contact point is formed as a tap contact point in a conductor track electrically connecting the first sensor element to the second sensor element.

10. The magnet sensor device according to claim 1, wherein at least the four sensor elements are electrically connected to a common supply voltage.

11. A production method for a magnet sensor device, comprising the following steps:
forming a measuring bridge device, which is configured with at least one measuring bridge and with at least four sensor elements in such a way that at least one measured value with respect to a magnetic field present at the measuring bridge device is determinable taking into consideration bridge potentials tapped at tap contact points of the measuring bridge device;
wherein a first sensor element of the at least four sensor elements, which is of a first sensor element type and has a first sensitivity and/or a first measuring range along a specified first sensing axis, is arranged in a first sensor element layer on and/or above a first substrate surface of a first substrate;
wherein a second sensor element of the at least four sensor elements is arranged in a second sensor element layer, which lies, in a spatial direction oriented perpendicularly to the first substrate surface, on one side of the first sensor element layer spaced apart from the first sensor element layer;
wherein the second sensor element is formed in such a way that at least one of: (i) a second sensor element type of the second sensor element differs from the first sensor element type of the first sensor element, (ii) a second sensing axis of the second sensor element differs from the first sensing axis of the first sensor element, or (iii) a second sensitivity and/or a second measuring range of the second sensor element differs from the first sensitivity and/or the first measuring range of the first sensor element.
